(19) United States
(12) Patent Application Publication
(10) Pub. No.: US 2009/0250113 A1
(43) Pub. Date: Oct. 8, 2009

(54) SOLAR CELL

(75) Inventors: HAI-LIN SUN, Beijing (CN); KAI-LI JIANG, Beijing (CN); QUN-QING LI, Beijing (CN); SHOU-SHAN FAN, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: TSINGHUA UNIVERSITY, Beijing (CN); HON HAI PRECISION INDUSTRY CO., LTD., Tu-Cheng (TW)

(21) Appl. No.: 12/339,353

(22) Filed: Dec. 19, 2008

(30) Foreign Application Priority Data
Apr. 3, 2008 (CN) 200810066508.6

(51) Int. Cl. H01L 31/00

(52) U.S. Cl. 136/261; 977/948

(57) ABSTRACT

A solar cell includes a back electrode, a single crystal silicon substrate, and a carbon nanotube structure. The single crystal silicon substrate includes an upper surface and a lower surface. The back electrode is located on and electrically connected to the lower surface of the single crystal silicon substrate. The carbon nanotube structure is located on and connected to the upper surface of the single crystal silicon substrate. The carbon nanotube structure includes an upper surface and a lower surface.

This application is related to commonly-assigned applications entitled, “SOLAR CELL”, filed ______ (Atty. Docket No. US18561); “SOLAR CELL”, filed ______ (Atty. Docket No. US18563); “SOLAR CELL”, filed ______ (Atty. Docket No. US18564); “SOLAR CELL”, filed ______ (Atty. Docket No. US18565); and “SOLAR CELL”, filed ______ (Atty. Docket No. US18566). The disclosures of the above-identified applications are incorporated herein by reference.

### BACKGROUND

1. Field of the Invention

The present invention relates to solar cells and, particularly, to a carbon nanotube film based solar cell.

2. Discussion of Related Art

Solar cells can be classified as source materials, such as silicon-based (single crystal, poly-crystalline and amorphous) solar cells and compound semiconductor-based solar cells. Among others, solar cells using single crystal silicon substrates are most widely fabricated by virtue of their excellent efficiency in energy conversion and low production cost. However, the manufacturing technology of single crystal silicon doesn't satisfy the demand for the development of solar cells. Furthermore, the manufacturing of solar cells consumes a large amount of electric energy. As a result, the cost of the solar cell is increased and the environment is further contaminated. What is needed, therefore, is to provide a novel solar cell.

Carbon nanotubes (CNTs) are novel carbonaceous materials and have received a great deal of interest since the early 1990s. Carbon nanotubes have interesting and potentially useful electrical conduction and light absorption properties. Due to these and other properties, CNTs play a significant role in the research and development of solar cells.

Referring to FIG. 4, a carbon nanotube based solar cell 30 includes a back electrode 32, a single crystal silicon substrate 34 and a carbon nanotube film 36 according to the prior art. The back electrode 32 is located on and connected to a lower surface 344 of the single crystal silicon substrate 34. The carbon nanotube film 36 is located on an upper surface 342 of the single crystal silicon substrate 34. The carbon nanotube film 36 is simultaneity used as photoelectric conversion material and an upper electrode. A thickness of the carbon nanotube film 36 approximately ranges from 50 to 200 nanometers. The carbon nanotubes in the carbon nanotube film 36 are distributed unevenly. A method for making the solar cell 30 includes the following steps: (a) providing a single crystal silicon substrate 34; (b) evaporating a metal film as a back electrode 32 on a surface of the single crystal silicon substrate 34, and leading in wires from the back electrode 32; (c) providing a carbon nanotube film 36; and (d) placing the carbon nanotube film 36 on another surface of the single crystal silicon substrate 34, and leading in wires from the carbon nanotube film 36. A method of making the carbon nanotube film 36 includes the following steps: (a) oxidizing carbon nanotubes in air; (b) immersing the carbon nanotubes in hydrogen peroxide; (c) adding strong acids into the hydrogen peroxide and washing the carbon nanotubes; and (d) adding alcohol or acetone, and making the carbon nanotubes float, then spreading the floated carbon nanotubes to form a carbon nanotube film 36. However, the carbon nanotubes in the carbon nanotube film 36 are distributed unevenly, and the resistance of the carbon nanotube film 36 is relatively large, so the photoelectric conversion efficiency is relatively low. Additionally, the method for making the carbon nanotube film 36 is complex.

What is needed, therefore, is to provide a solar cell with high photoelectric conversion efficiency and durability, along with a uniform distribution of resistance. Furthermore, a simple method for making the solar cell is needed.

### SUMMARY

A solar cell includes a back electrode, a single crystal silicon substrate, and a carbon nanotube structure. The single crystal silicon substrate includes an upper surface and a lower surface. The back electrode is located on and electrically connected to the lower surface of the single crystal silicon substrate. The carbon nanotube structure is located on and connected to the upper surface of the single crystal silicon substrate. The carbon nanotube structure includes an upper surface and a lower surface.

Other novel features and advantages of the present solar cell will become more apparent from the following detailed description of present embodiments when taken in conjunction with the accompanying drawings.

### BRIEF DESCRIPTION OF THE DRAWINGS

Many aspects of the present solar cell can be better understood with references to the following drawings. The components in the drawings are not necessarily drawn to scale, the emphasis instead being placed upon clearly illustrating the principles of the present solar cell.

FIG. 1 is a schematic, side view of a solar cell, in accordance with an exemplary embodiment.

FIG. 2 is an amplified diagram of an ordered carbon nanotube film segment used in the solar cell of FIG. 1; and

FIG. 3 is a schematic, top view of the solar cell of FIG. 1.

FIG. 4 is a schematic view of a conventional solar cell according to the prior art.

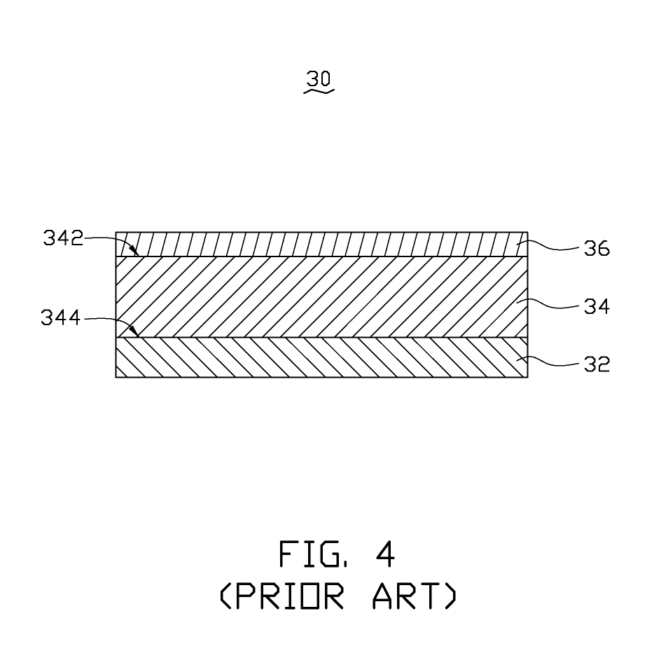

Corresponding reference characters indicate corresponding parts throughout the several views. The exemplifications set out herein illustrate at least one preferred embodiment of the solar cell, in at least one form, and such exemplifications are not to be construed as limiting the scope of the invention in any manner.

### DETAILED DESCRIPTION OF EXEMPLARY EMBODIMENTS

References will now be made to the drawings to describe, in detail, embodiments of the solar cell.

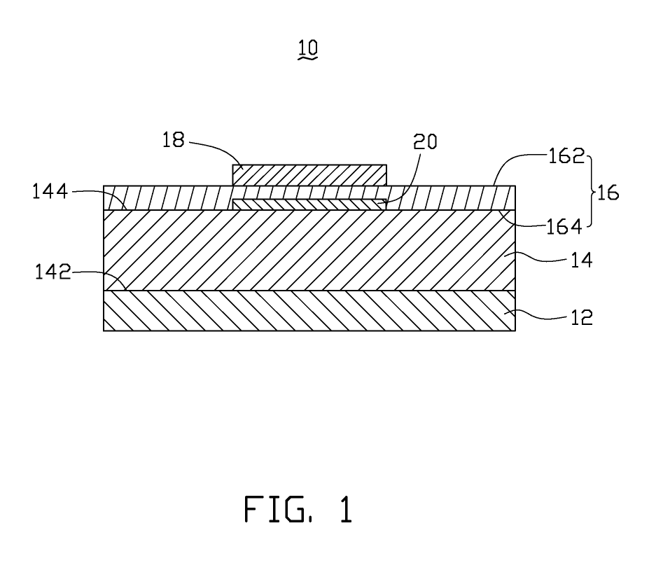

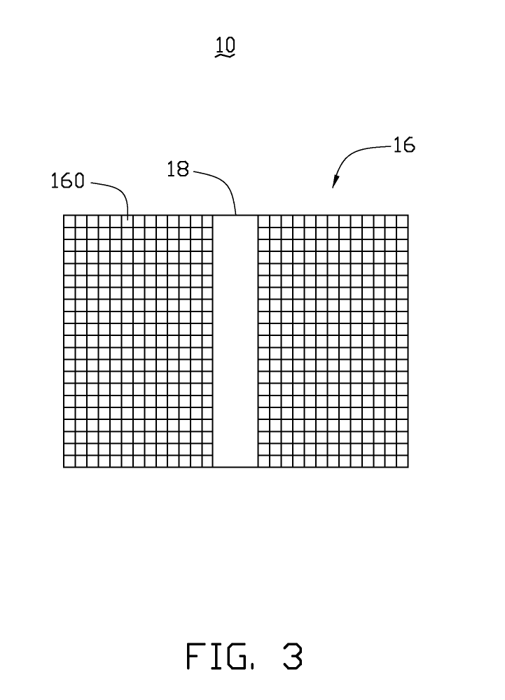

Referring to FIG. 1 and FIG. 3, a solar cell 10 includes a back electrode 12, a single crystal silicon substrate 14 and a carbon nanotube structure 16. The single crystal silicon substrate 14 includes a lower surface 142 and an upper surface 144. The back electrode 12 is located on and electrically connected to the lower surface 142 of the single crystal silicon substrate 14. The carbon nanotube structure 16 is located on and connected to the upper surface 144 of the single crystal silicon substrate 14. The carbon nanotube structure 16 includes an upper surface 162 and a lower surface 164.

The solar cell 10 can further include at least one electrode 18. The electrode 18 can be made of silver, gold, or carbon nanotubes. A shape and a thickness of the electrode 18 can be set as desired. The electrode 18 can be located on and connected to the upper surface 162 or the lower surface 164 of the carbon nanotube structure 16. The electrode 18 is used to collect the current of the carbon nanotube structure 16.

The solar cell 10 can further include at least one passivating layer 20. The passivating layer 20 can be made of silicon dioxide or silicon nitride. The shape and thickness of the passivating layer 20 can be set as desired. The passivating layer 20 can be located between the upper surface 144 of the single crystal silicon substrate 14 and the lower surface 164 of the carbon nanotube structure 16. The passivating layer 20 is used to reduce the combination speed of the electrons and holes at the interface of the single crystal silicon substrate 14 and the carbon nanotube structure 16, resulting in the improved photoelectric conversion efficiency of the solar cell 10.

The back electrode 12 is made of silver, aluminum, magnesium or any other suitable material. A thickness of the back electrode 12 approximately ranges from 10 to 300 microns. The shape and thickness of the back electrode 12 can be set as desired.

The single crystal silicon substrate 14 can be a P-type single crystal silicon substrate or an N-type single crystal silicon substrate. A thickness of the single crystal silicon substrate 14 approximately ranges from 200 to 300 microns. A plurality of heterojunctions are formed between the single crystal silicon substrate 14 and the carbon nanotube structure 16, achieving a conversion of solar radiation into electrical energy.

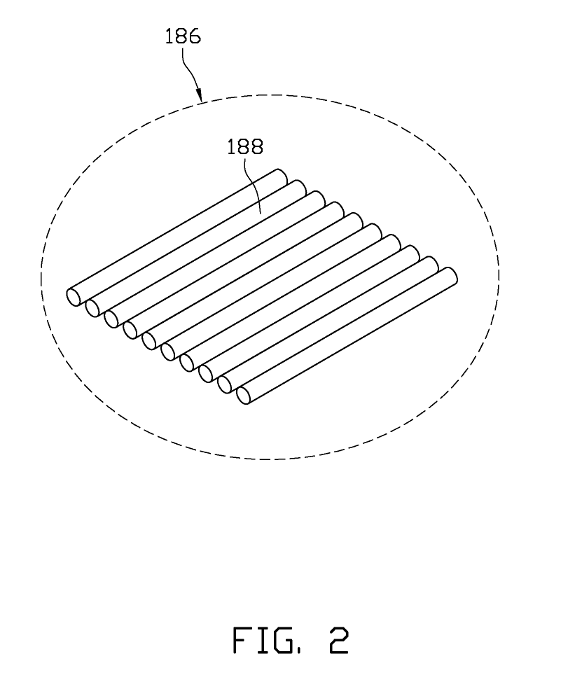

Referring to FIG. 2, the carbon nanotube structure 16 includes a plurality of uniformly distributed carbon nanotubes. The carbon nanotube structure 16 includes at least one ordered carbon nanotube film 160. The ordered carbon nanotube film 160 includes a plurality of carbon nanotube segments 166 including a plurality of carbon nanotubes 168. The carbon nanotubes 168 therein oriented along one direction or different directions.

The carbon nanotubes 168 of the carbon nanotube structure 16 can be selected from a group comprising of single-walled carbon nanotubes 168, double-walled carbon nanotubes 168, multi-walled carbon nanotubes 168, and combinations thereof. A diameter of the carbon nanotubes 168 approximately ranges from 0.5 to 50 nanometers. The carbon nanotube structure 16 can be directly adhered to the single crystal silicon substrate 14 due to its high purity and a large surface area of the carbon nanotubes 168.

In this embodiment, the carbon nanotube structure 16 includes at least one ordered carbon nanotube film 160. The carbon nanotube film 160 includes a plurality of continuously oriented and substantially parallel carbon nanotube segments 166 joined end-to-end by van der Waals attractive force. The carbon nanotube segments 166 can vary in width, thickness, uniformity and shape. Each carbon nanotube segment 166 includes a plurality of substantially parallel carbon nanotubes 168, wherein the carbon nanotubes 168 have approximately the same length and are substantially parallel to each other. Adjacent carbon nanotubes 168 are attracted by van der Waals attractive force.

The width of the carbon nanotube film 160 depends on the size of the carbon nanotube array. The length of the carbon nanotube film 160 is arbitrary. In this embodiment, the width of the carbon nanotube film 160 approximately ranges from 1 centimeter to 10 centimeters, and the thickness of the carbon nanotube film 160 approximately ranges from 0.01 to 100 microns.

Furthermore, the carbon nanotube structure 16 can include at least two stacked carbon nanotube films 160. Each carbon nanotube film 160 includes a plurality of carbon nanotubes 168 oriented along one direction. An angle between the aligned directions of the carbon nanotubes 168 in any two adjacent carbon nanotube films 160 ranges from 0° to 90°.

In use, the light transmission of the carbon nanotube structure 16 is good due to the interspaces between the adjacent carbon nanotubes 168. Sunlight is absorbed by the carbon nanotube structure 16, resulting in a plurality of mobile carriers (hole-electron pairs) produced at the interface of the single crystal silicon substrate 14 and the carbon nanotube structure 16. The hole-electron pairs are separated to a plurality of holes and electrons. The electrons move to the carbon nanotube structure 16 and can be collected by the electrode 18. The holes in the single crystal silicon substrate 14 move to the back electrode 12. Subsequently, the holes are collected by the back electrode 12 and an electric current goes through an electrical circuit outside the solar cell 10.

The ordered carbon nanotube film 160 can be fabricated by the substeps of: (a1) providing a substrate with a super-aligned array of carbon nanotubes 168 formed thereon; (a2) achieving an ordered carbon nanotube film 160 from the array of carbon nanotubes 168 by using a pulling tool (e.g., adhesive tape or another tool allowing multiple carbon nanotubes 168 to be gripped and drawn simultaneously).

In step (a1), a given super-aligned array of carbon nanotubes 168 can be formed by the substeps of: (a11) providing a substantially flat and smooth substrate; (a12) forming a catalyst layer on the substrate; (a13) annealing the substrate with the catalyst at a temperature approximately ranging from 700° C. to 900° C. in air for about 30 to 90 minutes; (a14) heating the substrate with the catalyst at a temperature approximately ranging from 500° C. to 740° C. in a furnace with a protective gas therein; and (a15) supplying a carbon source gas into the furnace for about 5 to 30 minutes and growing a super-aligned array of the carbon nanotubes 168 from the substrate.

In step (a11), the substrate can be a P-type silicon wafer, an N-type silicon wafer, or a silicon wafer with a film of silicon dioxide thereon. In the present embodiment, a 4-inch P-type silicon wafer is used as the substrate.

In step (a12), the catalyst can be made of iron (Fe), cobalt (Co), nickel (Ni), or any alloy thereof.

In step (a14), the protective gas can be made up of at least one of the following: nitrogen (N₂), ammonia (NH₃), and a noble gas. In step (a15), the carbon source gas can be a hydrocarbon gas, such as ethylene (C₂H₄), methane (CH₄), acetylene (C₂H₂), ethane (C₂H₆), or any combination thereof.

The super-aligned array of carbon nanotubes 168 can be approximately 200 to 400 microns in height and includes a plurality of carbon nanotubes 168 parallel to each other and substantially perpendicular to the substrate. The super-aligned array of carbon nanotubes 168 formed under the above conditions is essentially free of impurities, such as carbonaceous or residual catalyst particles. The carbon nanotubes 168 in the super-aligned array are packed together closely by van der Waals attractive force.

In step (a2), the ordered carbon nanotube film 160 can be drawn out from the super-aligned array of carbon nanotubes 168 by the substeps of: (a21) selecting one or more of carbon nanotubes 168 having a predetermined width from the super-aligned array of carbon nanotubes 168; and (a22) pulling the carbon nanotubes 168 to form nanotube segments 166 at an even/uniform speed to achieve a uniform carbon nanotube film 160.

In step (a21), the carbon nanotubes 168 having a predetermined width can be selected by using a pulling tool, such as a wide adhesive tape, to contact the super-aligned array. Each carbon nanotube segment 166 includes a plurality of carbon nanotubes 168 parallel to each other. In step (a22), the drawing direction is substantially along a direction perpendicular to the growing direction of the super-aligned array of carbon nanotubes 168.

More specifically, during the drawing process, as the initial carbon nanotube segments 166 are drawn out, other carbon nanotube segments 166 are also drawn out end-to-end due to van der Waals attractive force between ends of adjacent segments 166. This process of drawing ensures that a successive carbon nanotube film 160 can be formed. The carbon nanotubes 168 of the ordered carbon nanotube film 160 are all substantially parallel to the drawing direction, and the ordered carbon nanotube film 160 produced in such manner can be formed to have a selectable, predetermined width.

The width of the ordered carbon nanotube film 160 depends on the size of the carbon nanotube array. The length of the ordered carbon nanotube film 160 is arbitrary. In this embodiment, when the size of the substrate is 4 inches, the width of the ordered carbon nanotube film 160 approximately ranges from 1 centimeter to 10 centimeters, and the thickness of the ordered carbon nanotube film 160 approximately ranges from 0.01 to 100 microns.

The carbon nanotube structure 16 can include a plurality of carbon nanotube wires parallel to each other. The carbon nanotube wire has a small diameter and includes a plurality of carbon nanotubes 168 joined end-to-end by van der waals attractive force. The carbon nanotube structure 16 can be a multi-layer structure, wherein each layer includes a plurality of carbon nanotube wires parallel to each other, and an angle between the aligned directions of the carbon nanotube wires in any two adjacent layer ranges from 0° to 90°. The carbon nanotube structure 16 can also include at least one carbon nanotube film 160 and a plurality of carbon nanotube wires, wherein the carbon nanotube wires are located on the carbon nanotube film 160 in parallel.

Referring to table 1, n-Si denotes the single crystal silicon substrate 14, which is an N-type single crystal silicon substrate, while p-Si denotes the single crystal silicon substrate 14, which is a P-type single crystal silicon substrate. The carbon nanotube structure 16 includes at least two stacked ordered carbon nanotube films 160. An angle between the aligned directions of the carbon nanotubes 168 in any two adjacent carbon nanotube films 160 is 90°. The highest efficiency of the solar cell adopts four ordered and stacked carbon nanotube films 160 as the carbon nanotube structure 16.

TABLE 1
a parameter list of the solar cell

| | Parameters | | | | |
|---|---|---|---|---|---|
| | Open- | | | | |
| | circuit | Short | Best | Best | Effi- |
| | voltage | circuit | voltage | circuit | ciency |
| Basic component | (V) | (mA) | (V) | (mA) | (%) |
| n-Si: two ordered and | 0.41 | 6.36 | 0.15 | 2.8 | 0.42 |
| stacked carbon | | | | | |
| nanotube films | | | | | |
| n-Si: four ordered and | 0.42 | 9.1 | 0.2 | 4.2 | 0.84 |
| stacked carbon nanotube | | | | | |
| films | | | | | |
| n-Si: six ordered and | 0.4 | 7.8 | 0.16 | 3.4 | 0.55 |
| stacked carbon | | | | | |
| nanotube films | | | | | |
| n-Si: eight ordered and | 0.4 | 6.4 | 0.15 | 2.9 | 0.43 |
| stacked carbon nanotube | | | | | |
| films | | | | | |
| p-Si: four ordered and | 0.35 | 3 | 0.1 | 1 | 0.10 |
| stacked carbon nanotube | | | | | |
| films | | | | | |

Compared to the conventional solar cell, the present solar cell 10 has the following advantages: (1) the solar cell 10 has a high photoelectric conversion efficiency due to the excellent light absorption properties of the carbon nanotubes; (2) the solar cell 10 is durable due to the toughness of the carbon nanotubes; (3) the carbon nanotube structure 16 is easily obtained by using a tool to draw out the array of carbon nanotubes, decreasing the cost of the solar cell 10; (4) the carbon nanotube structure 16 has an uniform resistance distribution due to the uniform structure of the carbon nanotube structure 16; and (5) the light transmission of the carbon nanotube structure 16 is good due to the interspaces between the adjacent carbon nanotubes.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A solar cell comprising:
a single crystal silicon substrate comprising an upper surface and a lower surface;
a back electrode being located on the lower surface of the single crystal silicon substrate, and electrically connected to the single crystal silicon substrate; and
a carbon nanotube structure being located on the upper surface of the single crystal silicon substrate, and connected to the single crystal silicon substrate, the carbon nanotube structure comprising an upper surface and a lower surface.

2. The solar cell as claimed in claim 1, wherein the carbon nanotube structure comprises of carbon nanotubes that are parallel to a surface of the carbon nanotube structure.

3. The solar cell as claimed in claim 1, wherein the carbon nanotube structure comprises of carbon nanotubes and the carbon nanotubes are selected from a group comprising of single-walled carbon nanotubes, double-walled carbon nanotubes, multi-walled carbon nanotubes, and combinations thereof.

4. The solar cell as claimed in claim 3, wherein a diameter of the carbon nanotubes approximately ranges from 0.5 to 50 nanometers.

5. The solar cell as claimed in claim 1, wherein the carbon nanotube structure comprises of carbon nanotubes and the carbon nanotubes are uniformly distributed.

6. The solar cell as claimed in claim 5, wherein the carbon nanotube structure comprises at least one ordered carbon nanotube film, each carbon nanotube film comprises a plurality of carbon nanotubes aligned substantially in the same direction.

7. The solar cell as claimed in claim 6, wherein each carbon nanotube film comprises of carbon nanotube segments joined end-to-end by van der Waals attractive force.

8. The solar cell as claimed in claim 7, wherein each carbon nanotube segment comprises a plurality of substantially parallel carbon nanotubes, where the carbon nanotubes have approximately same length and are substantially parallel to each other.

9. The solar cell as claimed in claim 8, wherein adjacent carbon nanotubes are attracted by van der Waals attractive force therebetween.

10. The solar cell as claimed in claim 6, wherein the carbon nanotube structure comprises at least two carbon nanotube films stacked one on top of the other.

11. The solar cell as claimed in claim 10, wherein there is an angle between the aligned directions of the carbon nanotubes in any two adjacent carbon nanotube films.

12. The solar cell as claimed in claim 1, wherein the carbon nanotube structure comprises a plurality of carbon nanotube wires in parallel.

13. The solar cell as claimed in claim 1, wherein the carbon nanotube structure is a multi-layered structure, each layer comprises a plurality of carbon nanotube wires parallel to each other, and there is an angle between the aligned directions of the carbon nanotube wires in any two adjacent layers.

14. The solar cell as claimed in claim 1, wherein the carbon nanotube structure comprises at least one carbon nanotube film and a plurality of carbon nanotube wires, and the carbon nanotube wires are parallel to each other.

15. The solar cell as claimed in claim 1, wherein the single crystal silicon substrate is a P-type single crystal silicon substrate or an N-type single crystal silicon substrate.

16. The solar cell as claimed in claim 15, wherein a thickness of the single crystal silicon substrate approximately ranges from 200 to 300 microns.

17. The solar cell as claimed in claim 1, wherein the back electrode is made of a material selected from a group consisting of silver, aluminium, magnesium, and combinations thereof, and a thickness of the back electrode approximately ranges from 10 to 300 microns.

18. The solar cell as claimed in claim 1, further comprising at least one electrode, and the electrode is connected with the carbon nanotube structure.

19. The solar cell as claimed in claim 1, further comprising at least one passivating layer located between the upper surface of the single crystal silicon substrate and the lower surface of the carbon nanotube structure.

20. The solar cell as claimed in claim 19, wherein the passivating layer is made of silicon dioxide or silicon nitride.
